(19) United States
(12) Patent Application Publication
(10) Pub. No.: US 2014/0175633 A1
(43) Pub. Date: Jun. 26, 2014

(54) THERMALLY ENHANCED SEMICONDUCTOR ASSEMBLY WITH EMBEDDED CHIP AND INTERPOSER AND METHOD OF MANUFACTURING THE SAME

(71) Applicant: Bridge Semiconductor Corporation, Taipei (TW)

(72) Inventors: Charles W.C. LIN, Singapore (SG); Chia-Chung WANG, Hsinchu (TW)

(73) Assignee: Bridge Semiconductor Corporation, Taipei (TW)

(21) Appl. No.: 14/190,457

(22) Filed: Feb. 26, 2014

Related U.S. Application Data
(63) Continuation-in-part of application No. 13/615,819, filed on Sep. 14, 2012.
Application No. 13/615,819 is a continuation-in-part of application No. 13/753,625, filed on Jan. 30, 2013.
Application No. 13/753,625 is a continuation-in-part of application No. 13/615,819, filed on Sep. 14, 2012.
(60) Provisional application No. 61/895,506, filed on Oct. 25, 2013.
(60) Provisional application No. 61/682,801, filed on Aug. 14, 2012.
(60) Provisional application No. 61/682,801, filed on Aug. 14, 2012.

(51) Int. Cl. H01L 23/367; H01L 23/00

(52) U.S. Cl. CPC H01L 23/3672; H01L 24/97
USPC 257/712; 438/113

(57) ABSTRACT

The present invention relates to a method of making a thermally conductive semiconductor assembly. In accordance with a preferred embodiment, the method includes: providing a chip; providing an interposer that includes a through via, a first contact pad on a first surface and a second contact pad on an opposite second surface; electrically coupling the chip to the first contact pad of the interposer by a conductive bump or a wire; providing a heat sink with a cavity; then attaching the chip and the interposer on the heat sink using an adhesive with the chip inserted into the cavity; and then forming a build-up circuitry on the second surface of the interposer. Accordingly, the heat sink can provide essential thermal dissipation for the embedded chip, and the interposer and build-up circuitry can respectively provide first and second level fan-out routing/interconnection for the embedded chip.

### CROSS REFERENCE TO RELATED APPLICATION

This application is a continuation-in-part of U.S. application Ser. No. 13/615,819 filed Sep. 14, 2012 and a continuation-in-part of U.S. application Ser. No. 13/753,625 filed Jan. 30, 2013, each of which is incorporated by reference. This application also claims the benefit of filing date of U.S. Provisional Application Ser. No. 61/895,506 filed Oct. 25, 2013.

U.S. application Ser. No. 13/753,625 filed Jan. 30, 2013 is a continuation-in-part of U.S. application Ser. No. 13/615,819 filed Sep. 14, 2012. U.S. application Ser. No. 13/615,819 filed Sep. 14, 2012 and U.S. application Ser. No. 13/753,625 filed Jan. 30, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a thermally enhanced semiconductor assembly and a method of making the same, more particularly, to a thermally enhanced semiconductor with embedded chip and interposer and a method of making the same.

2. Description of Related Art

The convergence of mobility, communication, and computing has created significant thermal, electrical and cost challenges to the semiconductor packaging industry. For instance, semiconductor devices are susceptible to performance degradation as well as short life span, and may encounter immediate failure at high operating temperatures. In addition, semiconductor devices are often susceptible to undesirable electromagnetic interference (EMI) or other inter-device interference when they are densely packed together. The signal integrity of these devices can be adversely affected when they perform high frequency transmitting or receiving. As such, providing a semiconductor assembly that can provide adequate thermal dissipation, optimize signal integrity, assure high reliability and maintain low cost manufacturing is highly desirable.

U.S. Pat. No. 8,558,372 to Negoro, U.S. Pat. No. 8,350,263 to Oda, U.S. Pat. No. 7,859,101 to Zhao et al., U.S. Pat. No. 7,371,617 to Tsai et al., U.S. Pat. No. 7,230,831 to Luckner et al., and U.S. Pat. No. 7,094,966 to Bonitz et al., disclose an assembly in which a heat sink/spreader is mechanically attached to a wiring board and covers semiconductor chip to provide the desired heat dissipation function and/or electromagnetic shielding for the chip. As the heat sink is attached to the wiring board by adhesive or other mechanical means, any separation between the heat sink and the board would degrade the thermal performance of the chip. Furthermore, as the heat sink is mechanically supported by the wiring board, the wiring board's thermal stability and rigidity often affect package's reliability.

U.S. Pat. No. 5,353,498 to Fillion et al., U.S. Pat. No. 6,154,366 to Ma et al., and U.S. Pat. No. 6,701,614 to Ding et al. disclose an assembly in which semiconductor chip is enclosed in a molding compound and the molding compound serves as a supporting platform for fabricating fan-out routing circuitry. Since the molding compound is typically a poor thermal conductor, the heat generated from the enclosed chip would be completely blocked. Even though a portion of the molding compound can be removed to re-expose the chip and contacts external heat sink, the slow grinding process of removing the hardened molding compound can be expensive. Also, the assembly may suffer moisture penetration, voids and cracks at the chip interfaces which may cause serious reliability concerns.

U.S. Pat. No. 3,903,590 to Yokogawa discloses an assembly in which semiconductor chip is forcefully embedded in a metal plate before forming build-up layer to provide electrically connection for the embedded chip/chips. In this approach, the metal plate provides the heat sink for the chip and serves as the mechanical support for the routing circuitry. However, even though thermal issue can be resolved, applying a pressure of about 370 kg/cm² at a temperature of 100° C. to 200° C. to press the chip into the metal block is prohibitively cumbersome and prone to damage the chip. Furthermore, since there is no bonding material to accurately position and secure the embedded chip, voids and inconsistent bond lines arise between the chip and the heat slug. As a result, the assembly suffers from high yield loss, poor reliability and excessive cost.

U.S. Pat. No. 5,073,814 to Cole et al., U.S. Pat. No. 5,161,093 to Gorczyca et al., U.S. Pat. No. 5,422,513 to Marcinkiewicz et al., U.S. Pat. No. 5,434,751 and U.S. Pat. No. 5,745,984 to Cole et al., U.S. Pat. No. 6,709,898 to Ma, and U.S. Pat. No. 6,750,397 to Ou et al. disclose an assembly in which a semiconductor chip is housed in a cavity of a metal plate and the metal plate also serves as a supporting platform for build-up circuitry. In this approach, as the chip is protected by the metal cavity, lamination-induced chip cracking during build-up process can be largely avoided. However, since the build-up circuitry is directly formed on the chip surface and connected to the chip contact pad through microvia or post, the depth control of the metal cavity which dictates the co-planarity of the chip with the metal surface becomes extremely critical. Any protrusion or recess of the chip from the metal surface will affect the via/post reliability and may cause electrical disconnection between the chip and the build-up layers. Furthermore, as the semiconductor chip is placed in the cavity by adhesive or solder, lateral movement of the chip during die attach process often results in via/pad misalignment.

U.S. Patent Application No. 2013/0049188 to Choi et al., U.S. Patent Application No. 2013/0075937 to Wang et al., U.S. Patent Application No. 2011/0291288 to Wu et al., U.S. Pat. No. 8,476,115 to Choi et al., U.S. Pat. No. 8,409,922 to Camacho et al., U.S. Pat. No. 8,379,400 to Sunohara et al., disclose an assembly in which semiconductor chip is electrically coupled to a first side of an interposer, and a packaging substrate is electrically coupled to an opposite side of the interposer. In this approach, interposer plays a critical role in fan-out routing for the chip contact pad before connecting to the packaging substrate with a larger bump size and pitch, thereby greatly improve assembly yield and cost.

In view of the various development stages and limitations in currently available packages for high power and high performance semiconductor devices, there is a need for a thermally enhanced semiconductor assembly that is cost effective, reliable, manufacturable, versatile, provides good signal integrity and has excellent heat spreading and dissipation capability.

### SUMMARY OF THE INVENTION

The present invention has been developed in view of such a situation, and an object thereof is to provide a thermally enhanced semiconductor assembly in which a chip is electrically coupled to an interposer and embedded in a cavity of a heat sink, and a build-up circuitry is formed on the interposer for fan out interconnection.

In a preferred embodiment, the present invention provides a method of making a thermally enhanced semiconductor assembly that includes a chip, an interposer, an adhesive, a heat sink and build-up circuitry. The method for making the thermally enhanced semiconductor assembly can include: providing a chip; providing an interposer that includes a through via, a first contact pad on a first surface and a second contact pad on an opposite second surface, wherein the through via electrically couples the first contact pad and the second contact pad; electrically coupling the chip to the first contact pad of the interposer by a conductive bump or a wire; providing a heat sink with a cavity; attaching the chip and the interposer on the heat sink using an adhesive with the chip inserted into the cavity and the interposer laterally extending beyond the cavity; and forming a build-up circuitry on the second surface of the interposer, including electrically coupling the second contact pad of the interposer through a first conductive via of the build-up circuitry.

Electrically coupling the chip to the interposer can be performed on panel scale such as wafer, and a singulation step can be executed to separate individual interposer pieces each with the chip electrically coupled thereon before attaching the chip and the interposer on the heat sink. For instance, multiple chips can be electrically coupled to first contact pads of a panel-scale interposer (such as wafer-scale interposer) by conductive bumps or wires to provide a panel-scale assembly; and then the panel-scale assembly can be diced into individual chip-on-interposer packages, followed by attaching the chip-on-interposer package on the heat sink. For the bump interconnection, thermal compression, solder reflow or thermosonic bonding can be used to electrically couple the chip to the interposer by one or more conductive bumps that contact I/O pads on an active surface of the chip and the first contact pads of the interposer. As for the wire interconnection, the chip can be attached on the first surface of the interposer using an adhesive with its inactive surface facing the interposer, and be electrically coupled to the interposer by one or more wires that contact I/O pads on an inactive surface of the chip and the first contact pads of the interposer.

The heat sink may further include an alignment guide beyond or within the cavity to provide critical placement accuracy for the chip-on-interposer package. More specifically, the alignment guide may be located around the cavity entrance or located on the cavity bottom. For the aspect of the heat sink with the alignment guide beyond the cavity, providing the heat sink can include: providing a metallic base sheet; forming a cavity in the metallic base sheet; and forming an alignment guide around an entrance of the cavity by removing a selected portion of the metallic base sheet or by pattern deposition of a metal or a plastic material on the metallic base sheet. As an alternative for the heat sink with the alignment guide beyond the cavity, providing the heat sink can include: providing a laminated substrate that includes a dielectric layer and a metallic base sheet; forming an alignment guide on the dielectric layer by removing a selected portion of a metal layer on the dielectric layer or by pattern deposition of a metal or a plastic material on the dielectric layer; and forming a cavity that extends through the dielectric layer and optionally extends into the metallic base sheet. As for another aspect of the heat sink with the alignment guide within the cavity, providing the heat sink can include: providing a metallic base sheet; forming an alignment guide at a surface of the metallic base sheet by removing a selected portion of the metallic base sheet or by pattern deposition of a metal or a plastic material on the metallic base sheet; and providing a base layer on the metallic base sheet with the alignment guide located within an aperture of the base layer.

Attaching the chip and the interposer on the heat sink using an adhesive can include: dispensing an adhesive on the heat sink; and inserting the chip of the chip-on-interposer package into the cavity. The adhesive can be dispensed on the cavity bottom and then be squeezed partially out of the cavity when inserting the chip into the cavity. The squeezed out portion can contact and be sandwiched between the first surface of the interposer and the flat surface of the heat sink that laterally extends from the cavity entrance. Accordingly, the adhesive can provide robust mechanical bonds between the chip and the heat sink and between the interposer and the heat sink. For thermal dissipation consideration, thermally conductive adhesive is typically used.

Further, the interposer placement accuracy can be provided by the alignment guide of the heat sink. For the heat sink with the alignment guide beyond the cavity, the interposer can be attached to the heat sink with the alignment guide laterally aligned with and in close proximity to peripheral edges of the interposer. Accordingly, attaching the chip and the interposer can include: inserting the chip into the cavity with the alignment guide laterally aligned with and in close proximity to peripheral edges of the interposer. As the alignment guide extends beyond the first surface of the interposer in the second vertical direction, the undesirable lateral movement of the chip-on-interposer package during curing the adhesive can be stopped by the alignment guide. As for the heat sink with the alignment guide within the cavity, the chip can be attached to the heat sink with the alignment guide laterally aligned with and in close proximity to peripheral edges of the chip. Accordingly, attaching the chip and the interposer can include: inserting the chip into the cavity with the alignment guide laterally aligned with and in close proximity to peripheral edges of the chip. Likewise, the placement accuracy of the chip-on-interposer package can be provided by the alignment guide that extends beyond the inactive surface of the chip in the second vertical direction. As a result, the chip-on-interposer package can be affixed and mechanically connected to the heat sink at predetermined location defined by the alignment guide. Interposer attachment can also be executed without the alignment guide. Although the cavity cannot provide placement accuracy for the interposer because of control difficulties in cavity size and depth, it does not result in micro-via connection failure in the subsequent process of forming build-up circuitry on the interposer due to the larger pad size and pitch of the interposer.

The build-up circuitry can include a balancing layer, a first insulating layer and one or more first conductive traces. For instance, the balancing layer laterally covers sidewalls of the interposer, the first insulating layer is deposited on the second surface of the interposer and the balancing layer, and the first conductive traces extend laterally on the first insulating layer. As a result, forming the build-up circuitry can include: providing a balancing layer that laterally covers sidewalls of the interposer; providing a first insulating layer on the second surface of the interposer and the balancing layer; then forming one or more first via openings that extend through the first insulating layer and are aligned with one or more second contact pads of the interposer, and optionally forming one or more additional first via openings that extend through the first insulating layer and the balancing layer and are aligned with a selected portion of the heat sink; and then forming one or more first conductive traces that extend laterally on the first insulating layer and extend through the first via openings to form one or more first conductive vias in direct contact with the second contact pads of the interposer and optionally with the heat sink. Accordingly, the first conductive traces can directly contact the second contact pads to provide signal routing for the interposer, and thus the electrical connection between the interposer and the build-up circuitry can be devoid of solder. Besides, the first conductive traces can also directly contact the heat sink for ground connection.

The first insulating layer and the first conductive traces can have flat elongated surfaces that face in the second vertical direction. Furthermore, the build-up circuitry can further include additional insulating layers, additional via openings, and additional conductive traces if needed for further signal routing.

The outmost conductive traces of the build-up circuitries can include one or more terminal pads to provide electrical contacts for the next level assembly or another electronic device such as a semiconductor chip, a plastic package or another semiconductor assembly. The terminal pads can include an exposed contact surface that faces in the second vertical direction. As a result, the next level assembly or another electronic device can be electrically connected to the embedded chip using a wide variety of connection media including gold or solder bumps on the electrical contacts (i.e. the terminal pads of the build-up circuitry).

Forming the conductive trace can include depositing a plated layer on the insulating layer that extends through the via opening to form the conductive via and then removing selected portions of the plated layer using an etch mask that defines the conductive trace.

The balancing layer and the insulating layers can be deposited and extend to peripheral edges of the assembly by numerous techniques including film lamination, roll coating, spin coating and spray-on deposition. The via openings can be formed through the insulating layers by numerous techniques including laser drilling, plasma etching and photolithography. The plated layers can be deposited by numerous techniques including electroplating, electroless plating, evaporating, sputtering, and their combinations as a single layer or multiple layers. The plated layers can be patterned by numerous techniques including wet etching, electro-chemical etching, laser-assist etching, and their combinations to define the conductive traces.

By the above-mentioned method, the present invention can provide a thermally enhanced semiconductor assembly that includes a chip, an interposer, an adhesive, a heat sink and build-up circuitry, wherein (i) the chip is electrically coupled to the first contact pad of the interposer by a conductive bump or a wire and is positioned within the cavity of the heat sink; (ii) the interposer extends laterally beyond the cavity with the first surface of the interposer attached to a flat surface of the heat sink that is adjacent to and laterally extends from the cavity entrance; (iii) the adhesive contacts and is sandwiched between the chip and the heat sink and between the interposer and the heat sink; and (iv) the build-up circuitry is disposed adjacent to the interposer and the heat sink and is electrically coupled to the second contact pad of the interposer through a first conductive via of the build-up circuitry.

The heat sink can extend to peripheral edges of the assembly to provide mechanical support for the chip, the interposer and the build-up circuitry. In a preferred embodiment, the heat sink includes a metallic base sheet to provide essential thermal dissipation for the embedded chip. The metallic base sheet can have a thickness of 0.1 mm to 10 mm. The material of the metallic base sheet can be selected for the thermal dissipation consideration, and include copper, aluminum, stainless steel or their alloys. The heat sink can be a single-layer structure or multi-layer structure, and include a cavity extending into the metallic base sheet or defined by an aperture of a base layer on the metallic base sheet. For instance, the heat sink may be a metallic base sheet with a cavity defined therein and a flat surface that laterally extends from the cavity entrance. Alternatively, the heat sink may be a laminate substrate including a metallic base sheet and a dielectric layer, and has a cavity that extends through the dielectric layer and extends into the metallic base sheet. Also, the heat sink may include a metallic base sheet and a base layer with an aperture, and the cavity is defined by the aperture of the base layer on the metallic base sheet. The base layer material can include epoxy, BT, polyimide and other kind of resin or resin/glass composite. As such, the heat from the chip can be dissipated through the metallic base sheet that provides a thermal contact surface at the cavity bottom. For the heat sink with the cavity defined in the metallic base sheet, the metallic sidewalls of the cavity also can serve as additional thermal contact surface for the chip in addition to the metallic bottom of the cavity.

Moreover, the heat sink may further include an alignment guide beyond or within the cavity for the interposer attachment. For the aspect of the heat sink with the alignment guide beyond the cavity, the alignment guide extends from a flat surface of the heat sink adjacent to the cavity entrance and extends beyond the first surface of the interposer in the second vertical direction. As for another aspect of the heat sink with the alignment guide within the cavity, the alignment guide extends from the flat surface of the metallic base sheet at the cavity bottom and extends beyond the inactive surface of the flip chip in the second vertical direction. As such, the interposer placement accuracy can be provided by the alignment guide that is laterally aligned with and in close proximity to peripheral edges of the interposer or the chip.

The alignment guide can be made of a metal, a photosensitive plastic material or non-photosensitive material. For instance, the alignment guide can consist essentially of copper, aluminum, nickel, iron, tin or their alloys. The alignment guide can also consist of epoxy or polyimide. Further, the alignment guide can have patterns against undesirable movement of the interposer or the chip. For instance, the alignment guide can include a continuous or discontinuous strip or an array of posts. Alternatively, the alignment guide may laterally extend to the peripheral edges of the heat sink and have inner peripheral edges that conforms to the peripheral edges of the interposer or the chip. Specifically, the alignment guide can be laterally aligned with four lateral surfaces of the interposer or the chip to stop the lateral displacement of the interposer or the chip. For instance, the alignment guide can be aligned along and conform to four sides, two diagonal corners or four corners of the interposer or the chip, and gaps in between the interposer and the alignment guide or between the chip and the alignment guide preferably is in a range of about 5 to 50 microns. As a result, the alignment guide located beyond the interposer or the chip can provide placement accuracy for the chip-on-interposer package. Besides, the alignment guide preferably has a height in a range of 5-200 microns.

The cavity of the heat sink can have a larger diameter or dimension at its entrance than at its bottom and a depth of 0.05 mm to 1.0 mm. For instance, the cavity can have a cut-off conical or pyramidal shape in which its diameter or dimension increases as it extends in the second vertical direction from its bottom to its entrance. Alternatively, the cavity can have a cylindrical shape with a constant diameter. The cavity can also have a circular, square or rectangular periphery at its entrance and its bottom.

The adhesive can surround the embedded chip within the cavity of the heat sink, and contact and provide robust mechanical bond between the chip and the heat sink. As such, the embedded chip can be mechanically and thermally connected to the heat sink through the adhesive within the cavity. Further, the squeezed out portion of the adhesive can contact and provide robust mechanical bond between the interposer and the heat sink. Accordingly, the chip and the interposer can be affixed on the heat sink.

The interposer laterally extends beyond the cavity and can be attached to the flat surface of the heat sink adjacent to the cavity entrance with its first surface facing the heat sink. The interposer can be a silicon, glass, ceramic, graphite or organic laminate interposer with a thickness of 50 to 500 microns, and can contain a pattern of traces that fan out from a fine pitch at the first contact pads to a coarse pitch at the second contact pads. Accordingly, the interposer can provide first level fan-out routing/interconnection for the embedded chip.

The build-up circuitry is disposed adjacent to the second surface of the interposer and can provide second level fan-out routing/interconnection. Besides, the build-up circuitry can further be electrically coupled to the metallic surface of the heat sink by additional conductive via for ground connection.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The chip is coupled to the interposer before built-in process, and therefore can avoid warping problem caused by substrate fabrication. The interposer provides first level fan-out routing/interconnection for the embedded chip/chips, whereas the build-up circuitry provides second level fan-out routing/interconnection. As the contact pad and pad pitch of the interposer can be designed to have larger size and space than the I/O pad and pitch of the embedded chip, the method characterized in forming the build-up circuitry on the interposer can greatly improve manufacturing yield compared to the types where the build-up circuitry is directly formed on the embedded chip. Further, the alignment guide provides critical placement accuracy for the interposer. As such, the shape or depth of the cavity that houses the embedded chip is not a critical parameter that needs tightly controlled. However, in the conventional embedded case, cavity size and depth dictate the alignment accuracy in the horizontal and vertical direction, and embedded chip often suffers serious micro-via misalignment problem due to control difficulties in deep etching or mechanical drilling. The heat sink can provide essential thermal dissipation, electromagnetic shielding and moisture barrier for the embedded chip, and also provides mechanical support for the chip, the interposer and the build-up circuitry. The direct electrical connection without solder between the interposer and the build-up circuitry is advantageous to high I/O and high performance. The assembly made by this method is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-14 are cross-sectional views showing a method of making a thermally enhanced semiconductor assembly that includes an interposer, chips, a heat sink and build-up circuitry in accordance with an embodiment of the present invention, in which

FIGS. 3A, 4A, 5A, 7A and 8A are top perspective views corresponding to FIGS. 3, 4, 5, 7 and 8;

FIGS. 15-19 are cross-sectional views showing a method of making another thermally enhanced semiconductor assembly with additional conductive vias in contact with the heat sink in accordance with another embodiment of the present invention, in which

FIGS. 15A and 16A are top perspective views corresponding to FIGS. 15 and 16;

FIGS. 20-26 are cross-sectional views showing a method of making yet another thermally enhanced semiconductor assembly with an laminate substrate as the heat sink in accordance with yet another embodiment of the present invention, in which

FIGS. 21A, 21A′, 22A and 23A are top perspective views corresponding to FIGS. 21, 21′, 22 and 23; and

FIGS. 27-32 are cross-sectional views showing a method of making further another thermally enhanced semiconductor assembly with an alignment guide within the cavity of the heat sink in accordance with further another embodiment of the present invention, in which

FIGS. 27A and 28A are top perspective views corresponding to FIGS. 27 and 28.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

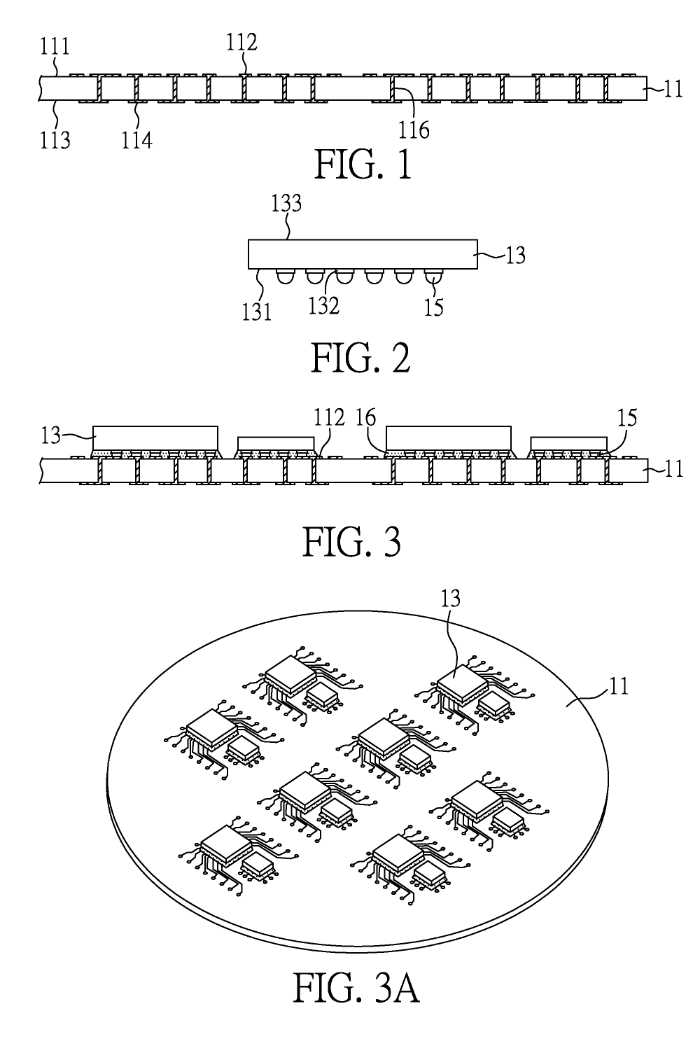

FIGS. 1-14 are cross-sectional views showing a method of making a thermally enhanced semiconductor assembly that includes an interposer, chips, a heat sink and build-up circuitry in accordance with an embodiment of the present invention.

As shown in FIG. 14, semiconductor assembly 110 includes interposer 11, chips 13, heat sink 20 and build-up circuitry 30. Interposer 11 and chips 13 are attached on heat sink 20 using adhesive 19 with chips 13 embedded in cavities 211 of heat sink 20 and alignment guide 213 laterally aligned with peripheral edges of interposer 11. Alignment guide 213 extends beyond first surface 111 of interposer 11 in the upward direction and is in close proximity to peripheral edges of interposer 11. Build-up circuitry 30 covers interposer 11 and heat sink 20 in the upward direction and is electrically coupled to second contact pads 114 of interposer 11 through first conductive vias 317.

FIGS. 1-5 are cross-sectional views showing a process of fabricating chip-on-interposer package in accordance with an embodiment of the present invention, and FIGS. 3A, 4A and 5A are top perspective views corresponding to FIGS. 3, 4 and 5, respectively.

FIG. 1 is a cross-sectional view of wafer-scale interposer 11, which includes first surface 111, second surface 113 opposite to first surface 111, first contact pads 112 at first surface 111, second contact pads 114 at second surface 113, and through vias 116 that electrically couples the first contact pads 112 and the second contact pads 114. Interposer 11 can be a silicon, glass, ceramic, graphite or organic laminate interposer that contains a pattern of traces that fan out from a fine pitch at first contact pads 112 to a coarse pitch at second contact pads 114.

FIG. 2 is a cross-sectional view of chip 13 with conductive bumps 15 mounted thereon. Chip 13 includes active surface 131, inactive surface 133 opposite to active surface 131, and I/O pads 132 at active surface 131. Conductive bumps 15 are mounted on I/O pads 132 of chip 13 and may be solder, gold or copper pillars.

FIGS. 3 and 3A are cross-sectional and top perspective views, respectively, of the wafer-scale assembly with chips 13 electrically coupled to interposer 11. Chips 13 can be electrically coupled to first contact pads 112 of interposer 11 using conductive bumps 15 by thermal compression, solder reflow or thermosonic bonding. Optionally, underfill 16 can be further provided to fill the gap between interposer 11 and chips 13.

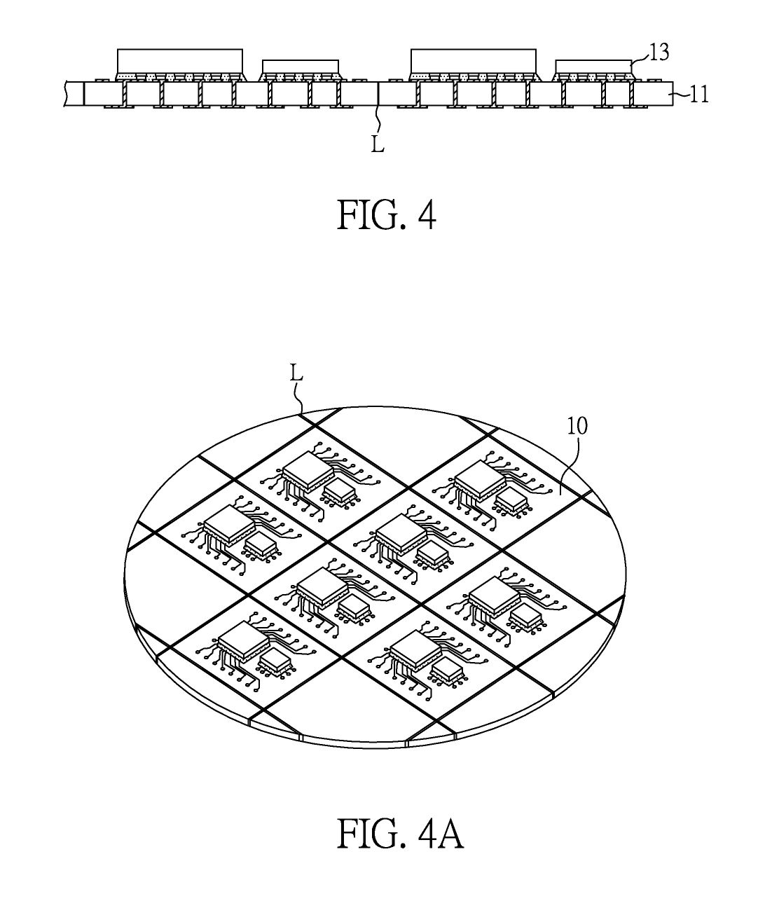

FIGS. 4 and 4A are cross-sectional and top perspective views, respectively, of the wafer-scale assembly diced into individual pieces. The wafer-scale assembly is singulated into individual chip-on-interposer packages 10 along dicing lines “L”.

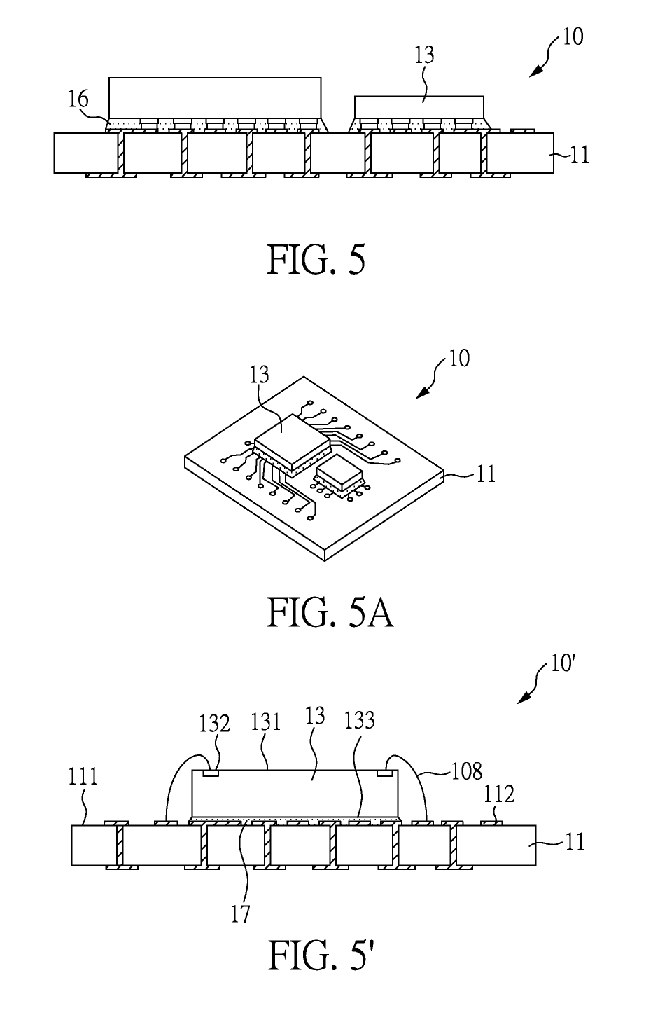

FIGS. 5 and 5A are cross-sectional and top perspective views, respectively, of the individual chip-on-interposer package 10. In this illustration, chip-on-interposer package 10 includes two chips 13 electrically coupled on diced interposer 11.

FIG. 5′ is a cross-sectional view of an alternative chip-on-interposer package 10′. As another aspect of chip-on-interposer package 10′, chip 13 is attached on interposer 11 at first surface 111 using adhesive 17 with its inactive surface 133 toward interposer 11, and I/O pads 132 of chip 13 at active surface 131 is electrically coupled to first contact pads 112 of interposer 11 through wires 18.

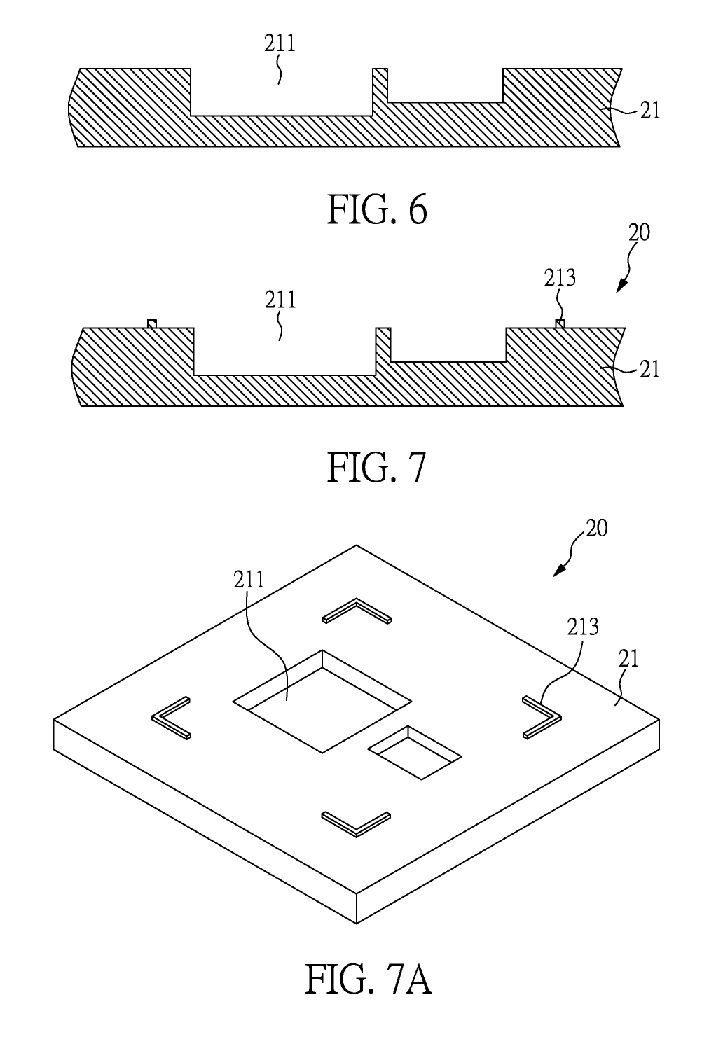

FIG. 6 is a cross-sectional view of metallic base sheet 21 with cavities 211. Metallic base sheet 21 can have a thickness of 0.1 mm to 10 mm, and include copper, aluminum, stainless steel or their alloys. In this embodiment, metallic base sheet 21 is illustrated as a copper sheet with a thickness of 2 mm. Cavities 211 can have different size and cavity depth. Cavity depth can range from 0.05 mm to 1.0 mm. In this illustration, one cavity is 0.26 mm (to house the 0.2 mm chip with 0.05 mm conductive bump) and another cavity is 0.21 mm (to house the 0.15 mm chip with 0.05 mm conductive bump).

FIGS. 7 and 7A are cross-sectional and top perspective views, respectively, of heat sink 20 provided with alignment guide 213 around entrance of cavities 211. Alignment guide 213 can be formed by removing selected portions of metallic base sheet 21 or by pattern deposition of metal or plastic material on metallic base sheet 21. Plating, etching or mechanical carving is typically used to form alignment guide 213 with a thickness of 5 to 200 microns. In this illustration, as shown in FIG. 7A, alignment guide 213 has a thickness of 50 microns and consists of a discontinuous strip in an arrangement that conforms to four corners of a subsequently disposed interposer. However, alignment guide patterns are not limited thereto and can be other various patterns against undesirable movement of the subsequently disposed interposer. For instance, alignment guide 213 also can consist of plural posts, and can be in an arrangement that conforms to four sides, two diagonal corners or four corners of a subsequently disposed interposer.

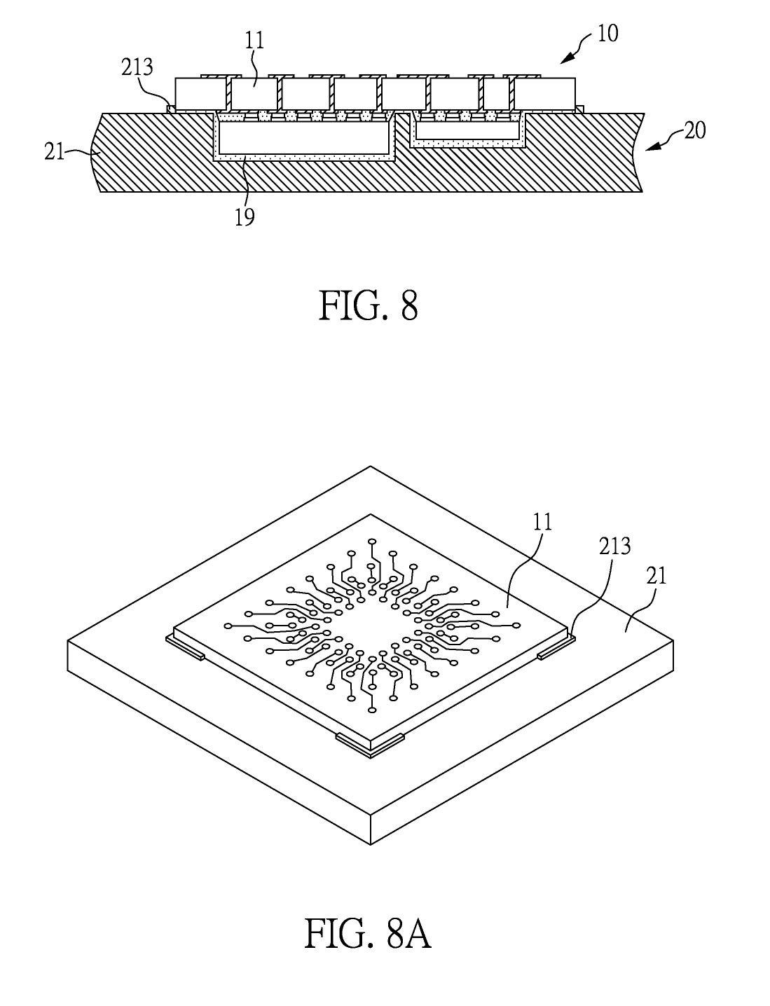

FIGS. 8 and 8A are cross-sectional and top perspective views, respectively, of the structure with interposer 11 and chips 13 attached on heat sink 20 using adhesive 19. Interposer 11 and chips 13 are mounted on heat sink 20 by dispensing adhesive 19 on cavity bottoms, and then inserting chips 13 of chip-on-interposer 10 into cavities 211 with alignment guide 213 laterally aligned with peripheral edges of interposer 11. Adhesive 19 (typically thermally conductive adhesive) within cavities 211 is compressed by chips 13, flows upward into gaps between chips 13 and cavity sidewalls, and overflows onto flat surface of metallic base sheet 21. As a result, adhesive 19 surrounds the embedded chips 13, and the squeezed out portion also serves as the interposer attach adhesive.

The interposer placement accuracy is provided by alignment guide 213. Alignment guide 213 extends from flat surface of metallic base sheet 21 and extends beyond first surface 111 of interposer 11 in the upward direction and is located beyond and laterally aligned with four corns of interposer 11 in the lateral directions. As alignment guide 213 is in close proximity to and conforms to four lateral surfaces of interposer 11 in lateral directions and adhesive 19 under interposer 11 is lower than alignment guide 213, any undesirable movement of chip-on-interposer package 10 due to adhesive curing can be avoided. Preferably, a gap in between interposer 11 and alignment guide 213 is in a range of about 5 to 50 microns. Interposer attachment can also be executed without alignment guide 213. Although cavities 211 cannot provide placement accuracy for chip-on-interposer package 10 due to control difficulties in cavity size and depth, it does not result in micro-via connection failure in the subsequent process of forming build-up circuitry on interposer 11 due to the larger pad size and pitch of interposer 11.

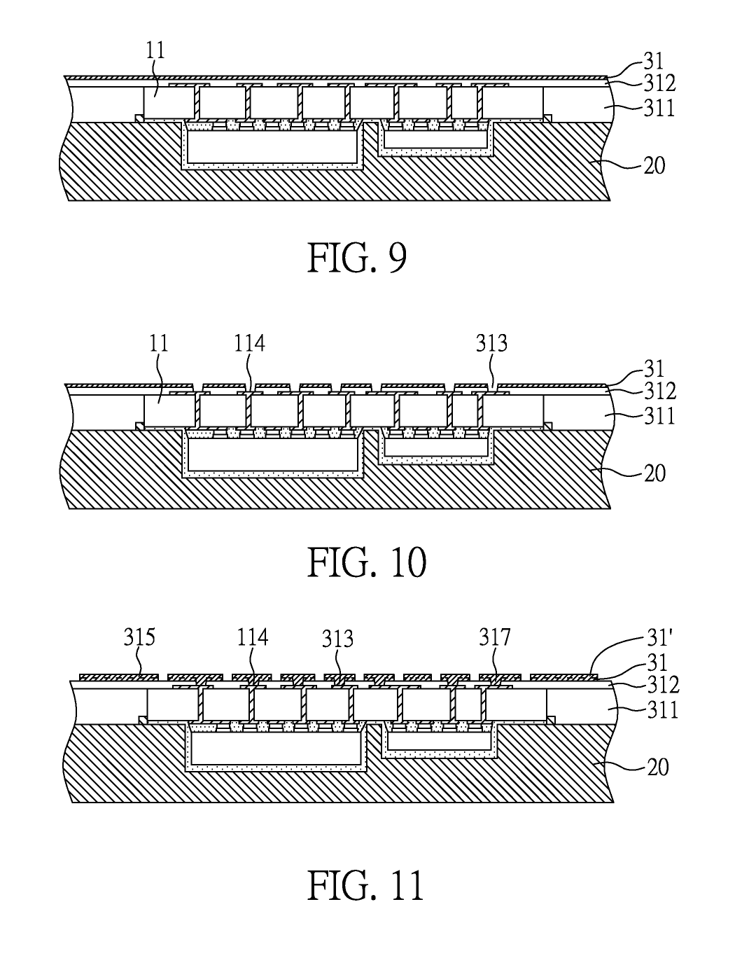

FIG. 9 is a cross-sectional view of the structure with balancing layer 311, first insulating layer 312 and first metal sheet 31 laminated/coated on interposer 11 and heat sink 20. Balancing layer 311 contacts and extends from heat sink 20 in the upward direction and laterally covers and surrounds and conformally coats sidewalls of interposer 11 and extends laterally from interposer 11 to peripheral edges of the structure. First insulating layer 312 contacts and covers interposer 11 and balancing layer 311 in the upward direction. First metal sheet 31 contacts and covers first insulating layer 312 in the upward direction. In this illustration, balancing layer 311 has a thickness of 0.2 mm which is close to the interposer thickness, and first insulating layer 312 typically has a thickness of 50 microns. Balancing layer 311 and first insulating layer 312 can be epoxy resin, glass-epoxy, polyimide and the like. First metal sheet 31 is illustrated as a copper layer with a thickness of 25 microns.

FIG. 10 is a cross-sectional view of the structure provided with first via openings 313. First via openings 313 extend through first metal sheet 31 and first insulating layer 312 and are aligned with second contact pads 114 of interposer 11. First via openings 313 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser.

Referring now to FIG. 11, first conductive traces 315 are formed on first insulating layer 312 by depositing first plated layer 31′ on first metal sheet 31 and into first via openings 313, and then patterning first metal sheet 31 as well as first plated layer 31′ thereon. Alternatively, when no first metal sheet 31 is laminated on first insulating layers 312 in the previous process, first insulating layers 312 can be directly metallized to form first conductive traces 315. First conductive traces 315 extend from first insulating layer 312 in the upward direction, extend laterally on first insulating layer 312 and extend into first via openings 313 in the downward direction to form first conductive vias 317 in direct contact with second contact pads 114 of interposer 11. As a result, first conductive traces 315 can provide signal routings for interposer 11.

First plated layer 31′ can be deposited by numerous techniques including electroplating, electroless plating, evaporating, sputtering, and their combinations as a single layer or multiple layers. For instance, it is deposited by first dipping the structure in an activator solution to render the insulating layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form first conductive traces 315 by numerous techniques including wet etching, electro-chemical etching, laser-assist etching, and their combinations with an etch masks (not shown) thereon that define first conductive traces 315.

First metal sheet 31 and first plated layer 31′ are shown as a single layer for convenience of illustration. The boundary (shown in phantom) between the metal layers may be difficult or impossible to detect since copper is plated on copper. However, the boundaries between first plated layer 31′ and first insulating layer 312 are clear.

FIG. 12 is a cross-sectional view of the structure with second insulating layer 322 and second metal sheet 32 laminated/coated on first insulating layer 312 and first conductive traces 315. Second insulating layer 322 sandwiched between first insulating layer 312/first conductive traces 315 and second metal sheet 32 can be epoxy resin, glass-epoxy, polyimide and the like and typically has a thickness of 50 microns. Second metal sheet 32 is illustrated as a copper layer with a thickness of 25 microns. Preferably, first insulating layer 312 and second insulating layer 322 are the same material.

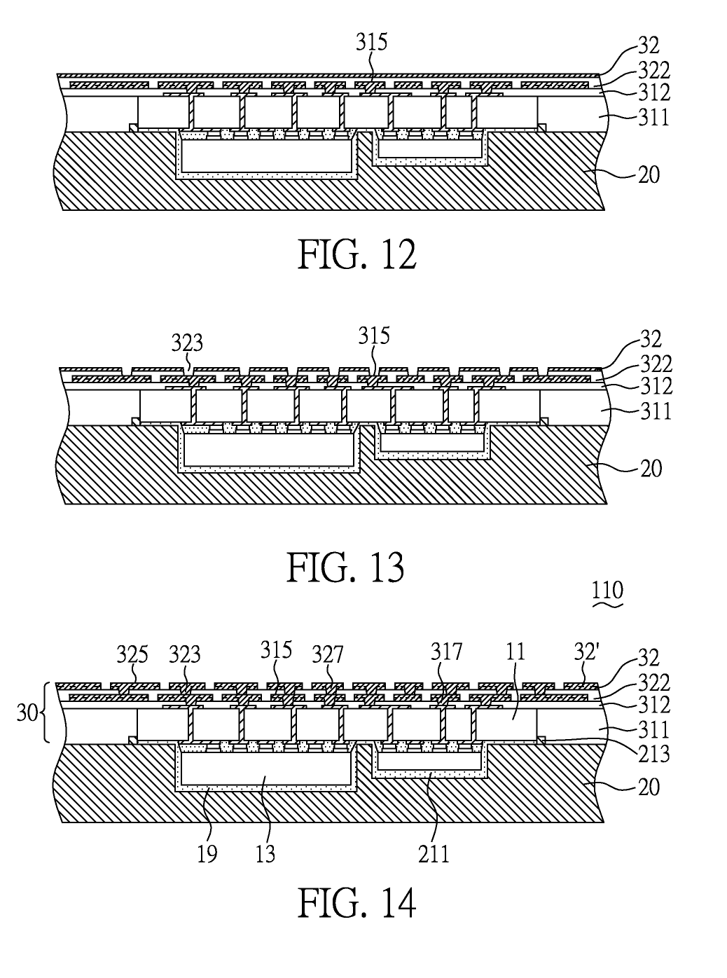

FIG. 13 is a cross-sectional view of the structure provided with second via openings 323 formed through second metal sheet 32 and second insulating layer 322 to expose selected portions of first conductive traces 315. Like first via openings 313, second via openings 323 can be formed by numerous techniques including laser drilling, plasma etching and photolithography and typically have a diameter of 50 microns. Preferably, first via openings 313 and second via openings 323 have the same size.

Referring now to FIG. 14, second conductive traces 325 are formed on second insulating layer 322 by depositing second plated layer 32′ on second metal sheet 32 and into second via openings 323, and then patterning second metal sheet 32 as well as second plated layer 32′ thereon. Alternatively, when no second metal sheet 32 is laminated on second insulating layers 322 in the previous process, second insulating layers 322 can be directly metallized to form second conductive traces 325. Second conductive traces 325 extend from second insulating layer 322 in the upward direction, extend laterally on second insulating layer 322 and extend into second via openings 323 in the downward direction to form second conductive vias 327 in electrical contact with first conductive traces 315. Preferably, first conductive traces 315 and second conductive traces 325 are the same material with the same thickness.

Accordingly, as shown in FIG. 14, semiconductor assembly 110 is accomplished and includes interposer 11, chips 13, heat sink 20 and build-up circuitry 30. In this illustration, build-up circuitry 20 includes balancing layer 311, first insulating layer 312, first conductive traces 315, second insulating layer 322 and second conductive traces 325.

Chips 13 are electrically coupled to the pre-fabricated interposer 11 by flip chip process to form chip-on-interposer package 10. Chip-on-interposer package 10 is attached on heat sink 20 using adhesive 19 with chips 13 positioned within cavities 211 and interposer 11 laterally extending beyond cavities 211. Adhesive 19 surrounds the embedded chips 13 and the squeezed out portion also serves as the interposer attach adhesive. Alignment guide 213 of heat sink 20 extends beyond first surface 111 of interposer 11 in the upward direction and is in close proximity to peripheral edges of interposer 11 to provide critical placement accuracy for interposer 11. Build-up circuitry 30 is electrically coupled to interposer 11 through first conductive vias 317 in direct contact with second contact pads 114 of interposer 11, and thus the electrical connection between interposer 11 and build-up circuitry 30 is devoid of solder.

### Embodiment 2

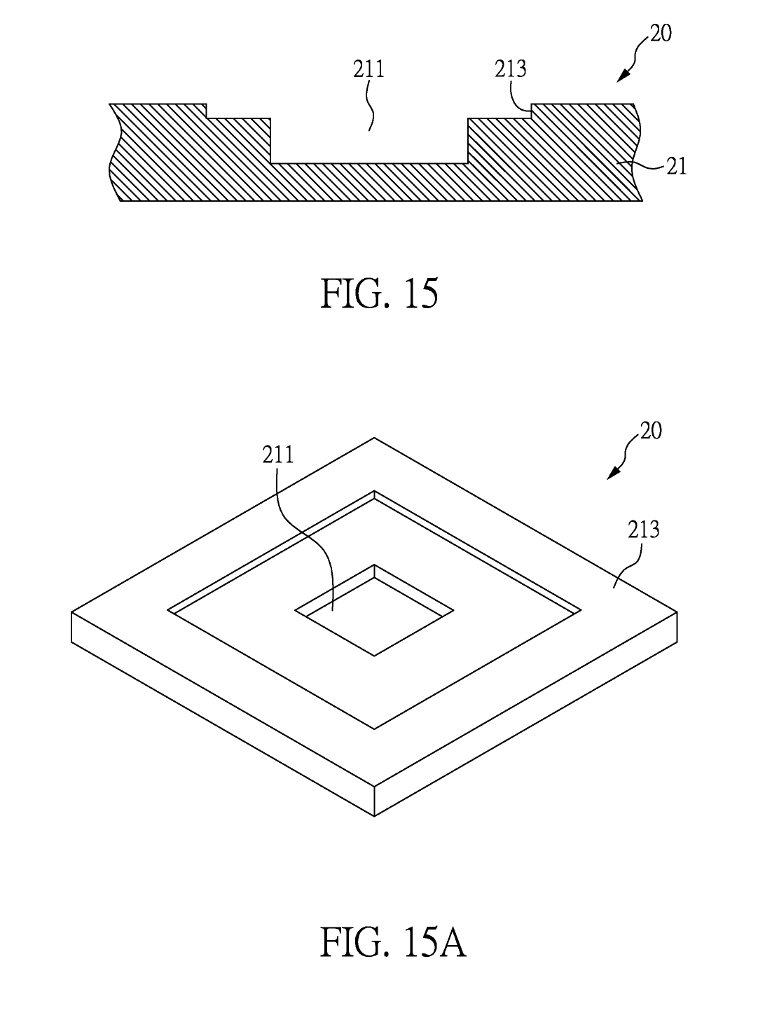

FIGS. 15-19 are cross-sectional views showing a method of making another thermally enhanced semiconductor assembly with additional conductive vias in contact with the heat sink in accordance with another embodiment of the present invention.

For purposes of brevity, any description in above Embodiment is incorporated herein insofar as the same is applicable, and the same description need not be repeated.

FIGS. 15 and 15A are cross-sectional and top perspective views, respectively, of heat sink 20 with alignment guide 213 around entrance of cavity 211. Alignment guide 213 can be formed by removing selected portions of metallic base sheet 21 or by pattern deposition including electroplating, electroless plating, evaporating, sputtering and their combinations using photolithographic process. In this illustration, as shown in FIG. 15A, alignment guide 213 laterally extends to the peripheral edges of heat sink 20 and has inner peripheral edges that conforms to four sides of a subsequently disposed interposer.

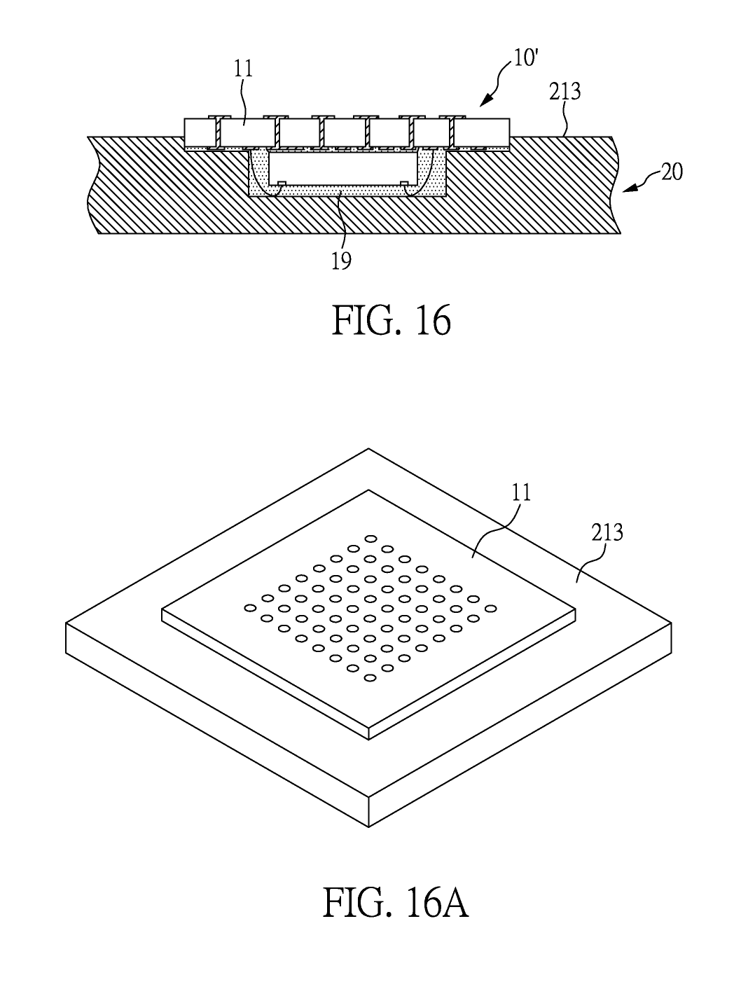

FIGS. 16 and 16A are cross-sectional and top perspective views, respectively, of the structure with chip-on-interposer package 10′ attached on heat sink 20 using adhesive 19. Interposer 11 and chip 13 are attached on heat sink 20 with chip 13 inserted into cavity 211 and alignment guide 213 laterally aligned with and in close proximity to peripheral edges of interposer 11. Adhesive 19 surrounds the embedded chip 13, and the squeezed out portion also serves as the interposer attach adhesive. Alignment guide 213 extends beyond first surface 111 of interposer 11 in the upward direction and is in close proximity to peripheral edges of interposer 11 to provide critical placement accuracy for interposer 11.

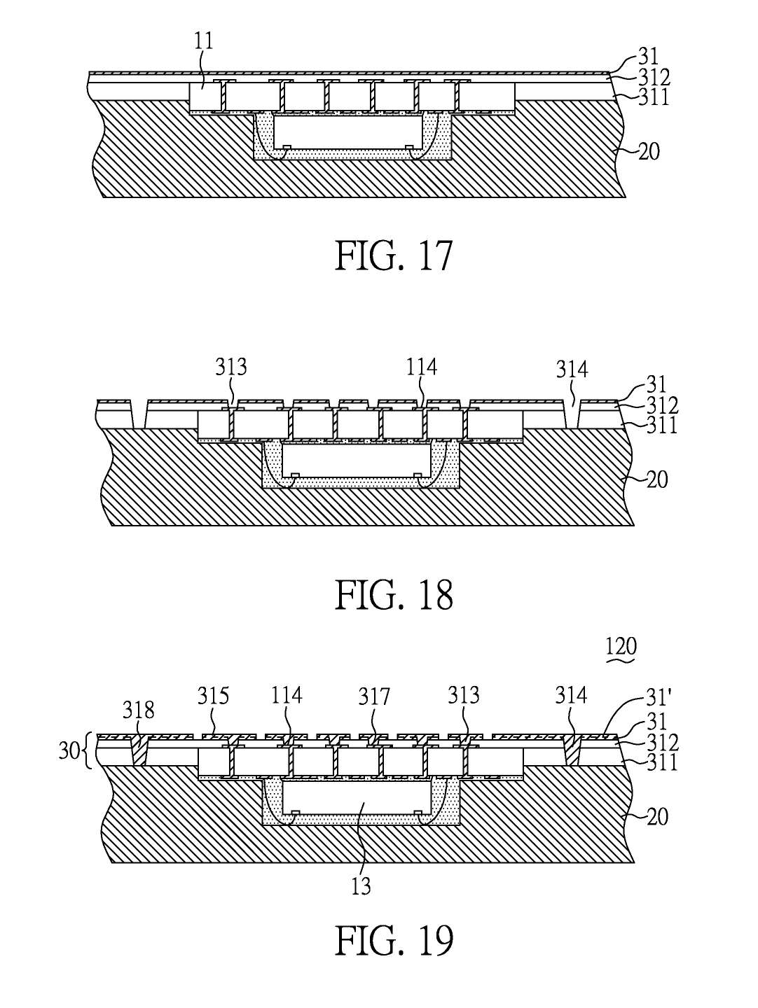

FIG. 17 is a cross-sectional view of the structure with balancing layer 311, first insulating layer 312 and first metal sheet 31 laminated/coated on interposer 11 and heat sink 20. Balancing layer 311 contacts and extends from heat sink 20 in the upward direction and laterally covers and surrounds and conformally coats sidewalls of interposer 11 and extends laterally from interposer 11 to peripheral edges of the structure. First insulating layer 312 contacts and provides robust mechanical bonds between first metal sheet 31 and interposer 11 and between first metal sheet 31 and balancing layer 311.

FIG. 18 is a cross-sectional view of the structure provided with first via openings 313, 314. First via openings 313 extend through first metal sheet 31 and first insulating layer 312 and are aligned with second contact pads 114 of interposer 11. Further, additional first via openings 314 extend through first metal sheet 31, first insulating layer 312 and balancing layer 311 and are aligned with selected portions of heat sink 20.

Referring now to FIG. 19, first conductive traces 315 are formed on first insulating layer 312 by depositing first plated layer 31′ on first metal sheet 31 and into first via openings 313, 314, and then patterning first metal sheet 31 as well as first plated layer 31′ thereon. First conductive traces 315 extend from first insulating layer 312 in the upward direction, extend laterally on first insulating layer 312 and extend into first via openings 313, 314 in the downward direction to form first conductive vias 317, 318 in direct contact with second contact pads 114 of interposer 11 and selected portions of heat sink 20. As a result, first conductive traces 315 can provide signal routings for interposer 11 and ground connection.

Accordingly, as shown in FIG. 19, semiconductor assembly 120 is accomplished and includes interposer 11, chip 13, heat sink 20 and build-up circuitry 30. In this illustration, build-up circuitry 30 includes balancing layer 311, first insulating layer 312 and first conductive traces 315. Chip 13 is electrically coupled to the pre-fabricated interposer 11 by wire bonding process to form chip-on-interposer package 10′. Chip-on-interposer package 10′ is attached on heat sink 20 using adhesive 19 with chip 13 positioned within cavity 211 and interposer 11 laterally extending beyond cavity 211. Adhesive 19 surrounds the embedded chip 13 and the squeezed out portion also serves as the interposer attach adhesive. Alignment guide 213 of heat sink 20 extends beyond first surface 111 of interposer 11 in the upward direction and is in close proximity to peripheral edges of interposer 11 to provide critical placement accuracy for interposer 11. Build-up circuitry 30 is electrically coupled to interposer 11 and heat sink 20 through first conductive vias 317, 318 in direct contact with second contact pads 114 of interposer 11 and selected portions of heat sink 20.

### Embodiment 3

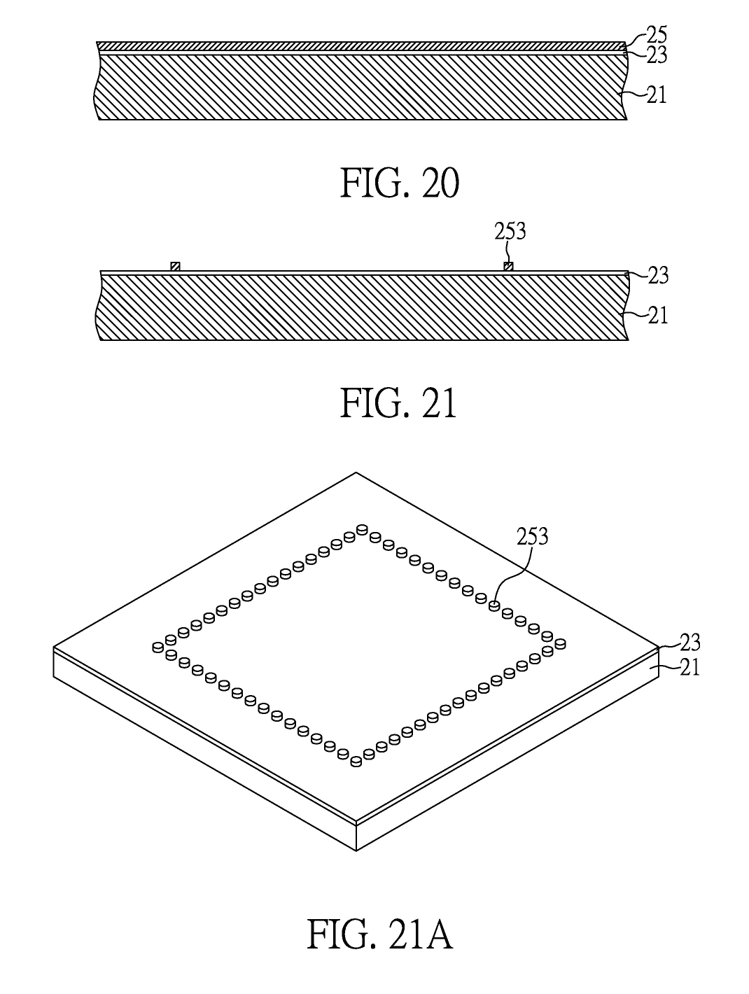

FIGS. 20-26 are cross-sectional views showing a method of making yet another thermally enhanced semiconductor assembly with an laminate substrate as the heat sink in accordance with yet another embodiment of the present invention.

For purposes of brevity, any description in above Embodiments is incorporated herein insofar as the same is applicable, and the same description need not be repeated.

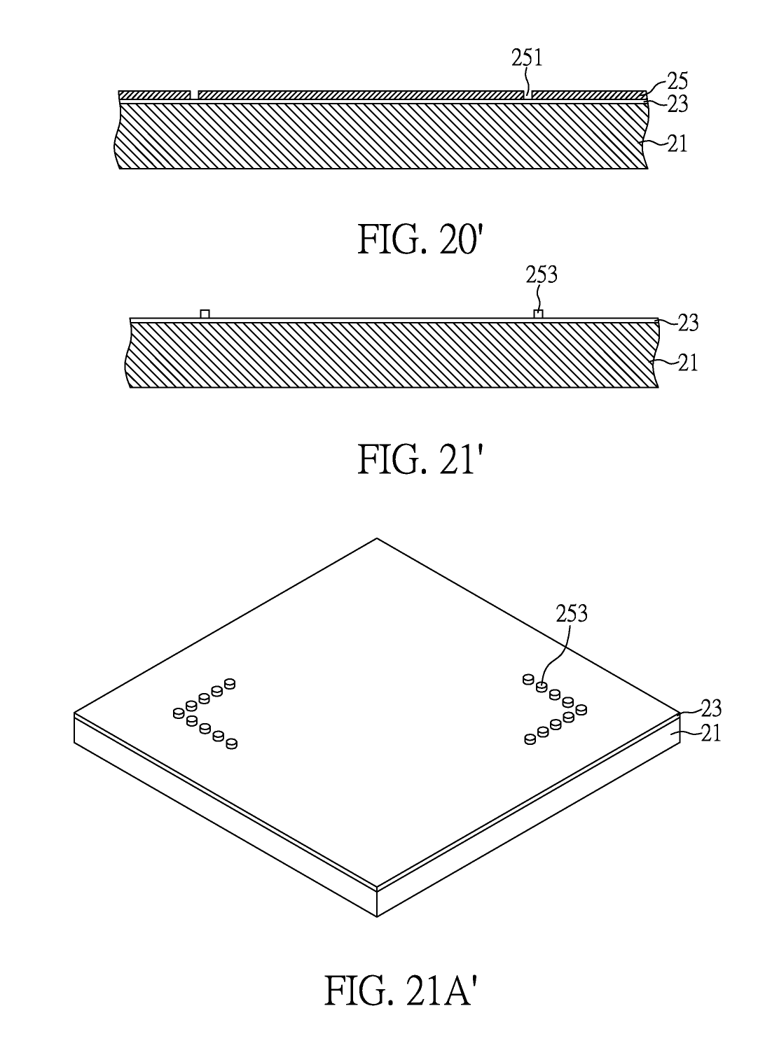

FIGS. 20 and 21 are cross-sectional views showing a process of forming an alignment guide on a dielectric layer of a laminated substrate in accordance with an embodiment of the present invention, and FIG. 21A is a top perspective view corresponding to FIG. 21.

FIG. 20 is a cross-sectional view of a laminate substrate that includes metallic base sheet 21, dielectric layer 23 and metal layer 25. Dielectric layer 23 is sandwiched between metallic base sheet 21 and metal layer 25. Dielectric layer 23 typically is made of epoxy resin, glass-epoxy, polyimide and the like and has a thickness of 50 microns. Metal layer 25 typically is made of copper, but copper alloys or other materials (such as aluminum, stainless steel or their alloys) are also doable. The thickness of metal layer 25 can range from 5 to 200 microns. In this embodiment, metal layer 25 is illustrated as a copper plate with a thickness of 50 microns.

FIG. 21 is a cross-sectional view of the structure with alignment guide 253 formed on dielectric layer 23. Alignment guide 253 can be formed by removing selected portions of metal layer 25 using photolithography and wet etching. In this illustration, alignment guide 253 consists of plural metal posts in a rectangular frame array and conforms to four sides of a subsequently disposed interposer. However, alignment guide patterns are not limited thereto and can be other various patterns against undesirable movement of the subsequently disposed interposer.

FIGS. 20′ and 21′ are cross-sectional views showing an alternative process of forming an alignment guide on a dielectric layer of a laminate substrate, and FIG. 21A′ is a top perspective view corresponding to FIG. 21′.

FIG. 20′ is a cross-sectional view of a laminate substrate with a set of openings 251. The laminate substrate includes metallic base sheet 21, dielectric layer 23 and metal layer 25 as above mentioned, and openings 251 are formed by removing selected portions of metal layer 25.

FIGS. 21′ and 21A′ are cross-sectional and top perspective views, respectively, of the structure with alignment guide 253 formed on dielectric layer 23. Alignment guide 253 can be formed by dispensing or printing a photosensitive plastic material (e.g., epoxy, polyimide, etc.) or non-photosensitive material into openings 251, followed by removing overall metal layer 25. Herein, alignment guide 253 is illustrated as an array of plural resin posts and conforms to two diagonal corners of a subsequently disposed interposer.

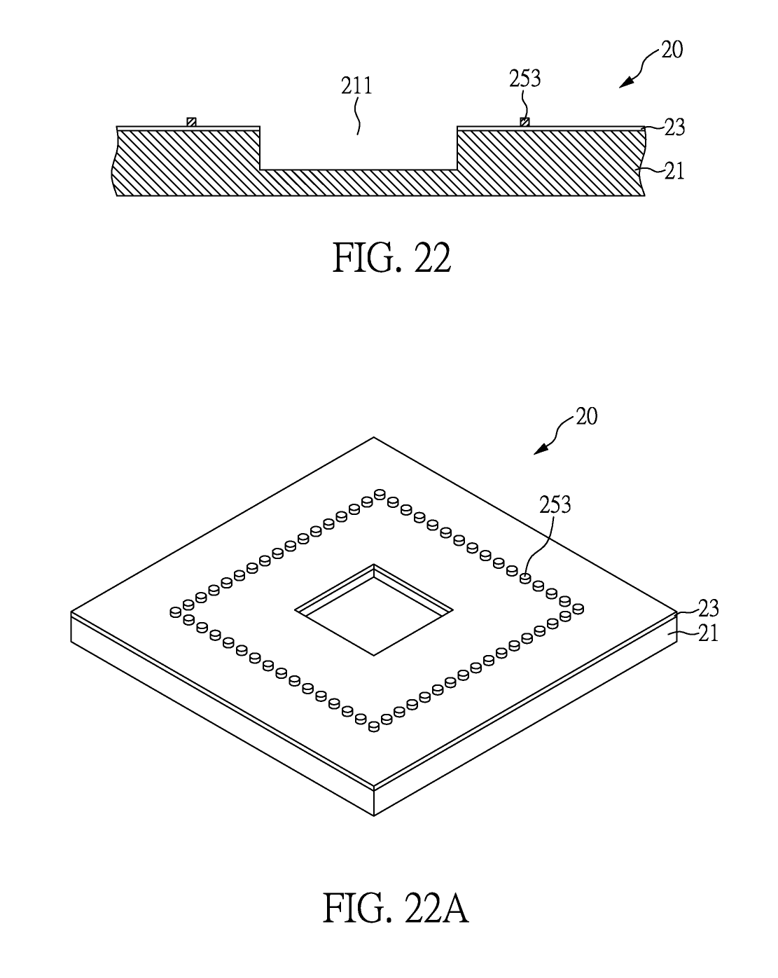

FIGS. 22 and 22A are cross-sectional and top perspective views, respectively, of heat sink 20 with cavity 211. Cavity 211 extends through dielectric layer 23 and further extends into metallic base sheet 21.

FIGS. 23 and 23A are cross-sectional and top perspective views, respectively, of the structure with chip-on-interposer package 10 attached on heat sink 20 using adhesive 19. Chip-on-interposer package 10 is similar to that illustrated in FIG. 5, except that single chip 13 is flip mounted on interposer 11 in this illustration. Chip 13 is positioned within cavity 211, and interposer 11 is located beyond cavity 211 with its first surface 111 attached on dielectric layer 23. Alignment guide 253 extends from dielectric layer 23 and extends beyond first surface 111 of interposer 11 in the upward direction and is in close proximity to peripheral edges of interposer 11 to provide critical placement accuracy for interposer 11.

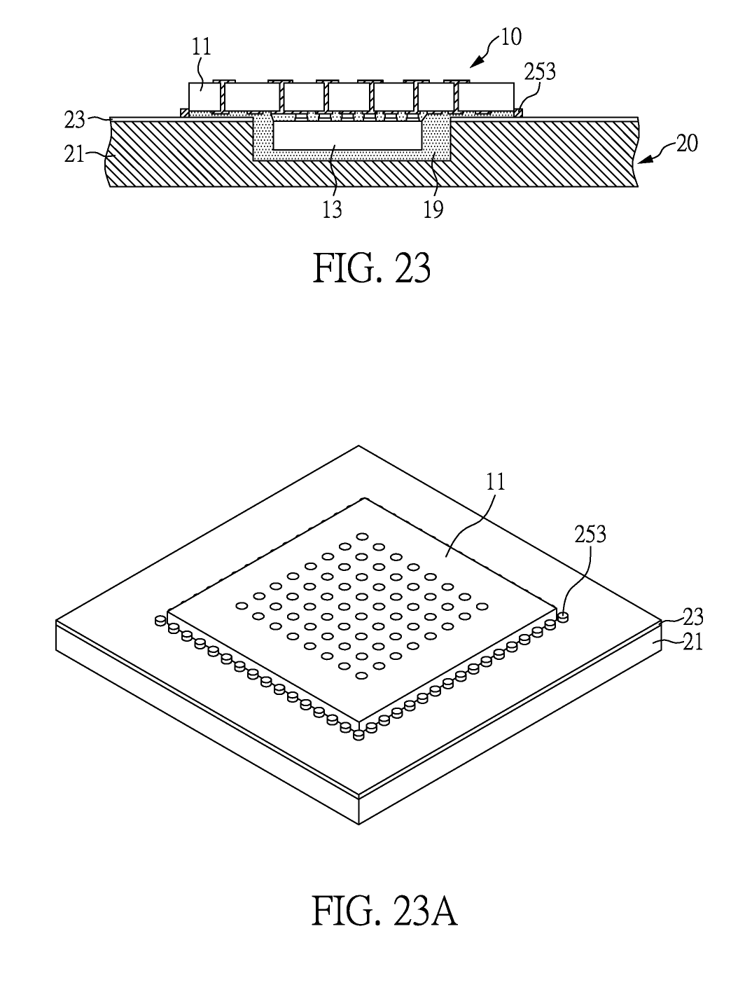

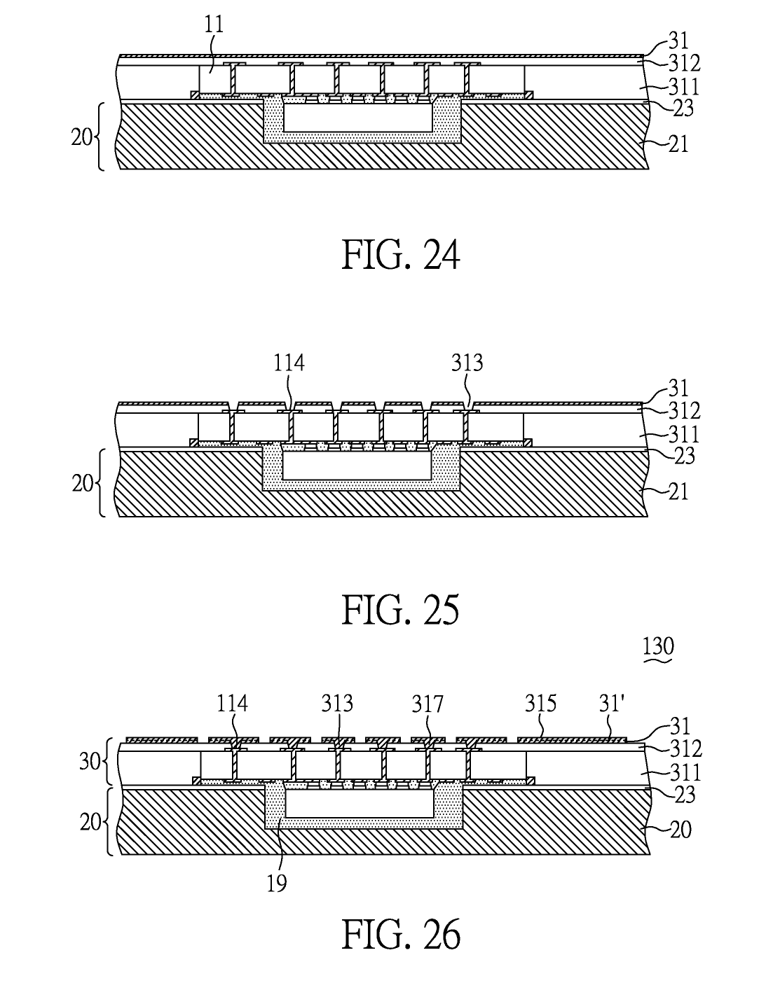

FIG. 24 is a cross-sectional view of the structure with balancing layer 311, first insulating layer 312 and first metal sheet 31 laminated/coated on interposer 11 and heat sink 20. Balancing layer 311 contacts and covers dielectric layer 23 of heat sink 20 and sidewalls of interposer 11. First insulating layer 312 contacts and provides robust mechanical bonds between first metal sheet 31 and interposer 11 and between first metal sheet 31 and balancing layer 311.

FIG. 25 is a cross-sectional view of the structure provided with first via openings 313. First via openings 313 extend through first metal sheet 31 and first insulating layer 312 and are aligned with second contact pads 114 of interposer 11.

Referring now to FIG. 26, first conductive traces 315 are formed on first insulating layer 312 by depositing first plated layer 31′ on first metal sheet 31 and into first via openings 313, and then patterning first metal sheet 31 as well as first plated layer 31′ thereon. First conductive traces 315 extend from first insulating layer 312 in the upward direction, extend laterally on first insulating layer 312 and extend into first via openings 313 in the downward direction to form first conductive vias 317 in direct contact with second contact pads 114 of interposer 11. As a result, first conductive traces 315 can provide signal routings for interposer 11.

Accordingly, as shown in FIG. 26, semiconductor assembly 130 is accomplished and includes interposer 11, chip 13, heat sink 20 and build-up circuitry 30. Chip 13 is electrically coupled to the pre-fabricated interposer 11 by flip chip process to form chip-on-interposer package 10. Heat sink 20 includes cavity 211 that extends through dielectric layer 23 and extends into metallic base sheet 21. Chip-on-interposer package 10 is attached on heat sink 20 using adhesive 19 with chip 13 positioned within cavity 211 and interposer 11 laterally extending beyond cavity 211. Adhesive 19 surrounds the embedded chip 13, and the squeezed out portion contacts and is sandwiched between first surface of interposer 11 and dielectric layer 23 and serves as the interposer attach adhesive. Alignment guide 213 of heat sink 20 extends from dielectric layer 23 and extends beyond first surface 111 of interposer 11 in the upward direction and is in close proximity to peripheral edges of interposer 11 to provide critical placement accuracy for interposer 11. Build-up circuitry 30 is electrically coupled to interposer 11 through first conductive vias 317 in direct contact with second contact pads 114 of interposer 11.

### Embodiment 4

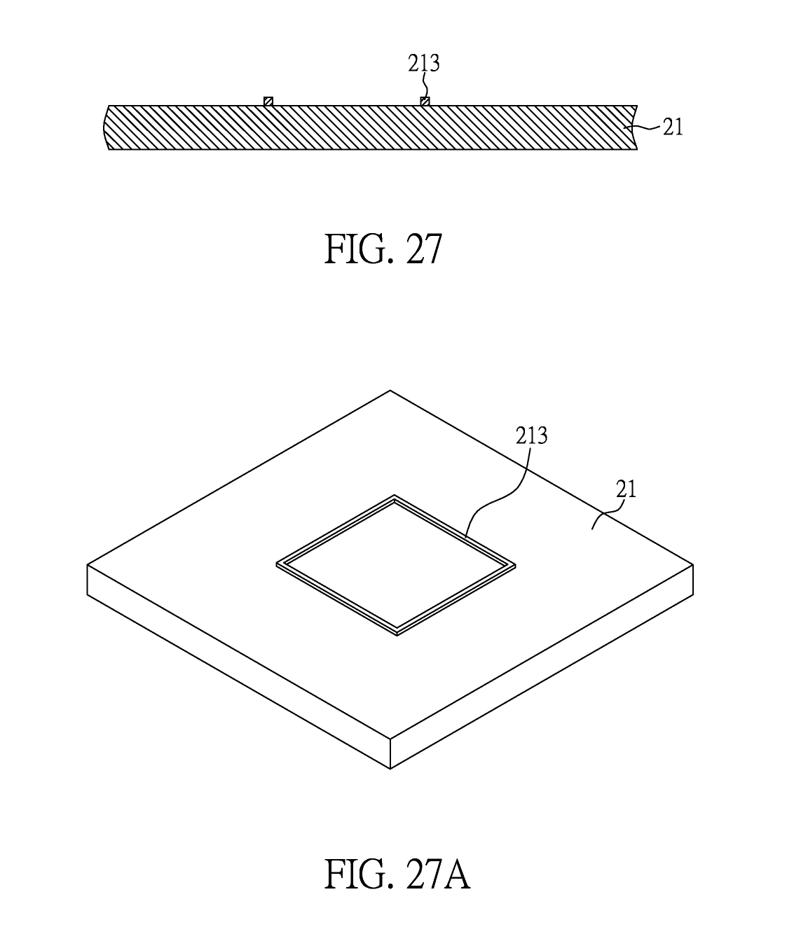

FIGS. 27-32 are cross-sectional views showing a method of making further another thermally enhanced semiconductor assembly with an alignment guide within the cavity of the heat sink in accordance with further another embodiment of the present invention.

For purposes of brevity, any description in above Embodiments is incorporated herein insofar as the same is applicable, and the same description need not be repeated.

FIGS. 27 and 27A are cross-sectional and top perspective views, respectively, of the structure with alignment guide 213 formed on metallic base sheet 21. Metallic base sheet 21 is illustrated as a copper sheet with a thickness of 1 mm. Alignment guide 213 can be formed by removing selected portions of metallic base sheet 21 or by pattern deposition of metal or plastic material on metallic base sheet 21. In this illustration, alignment guide 213 consists of a continuous metal strip in a rectangular frame arrangement and conforms to four sides of a subsequently disposed chip. However, alignment guide patterns are not limited thereto and can be other various patterns against undesirable movement of the subsequently disposed chip.

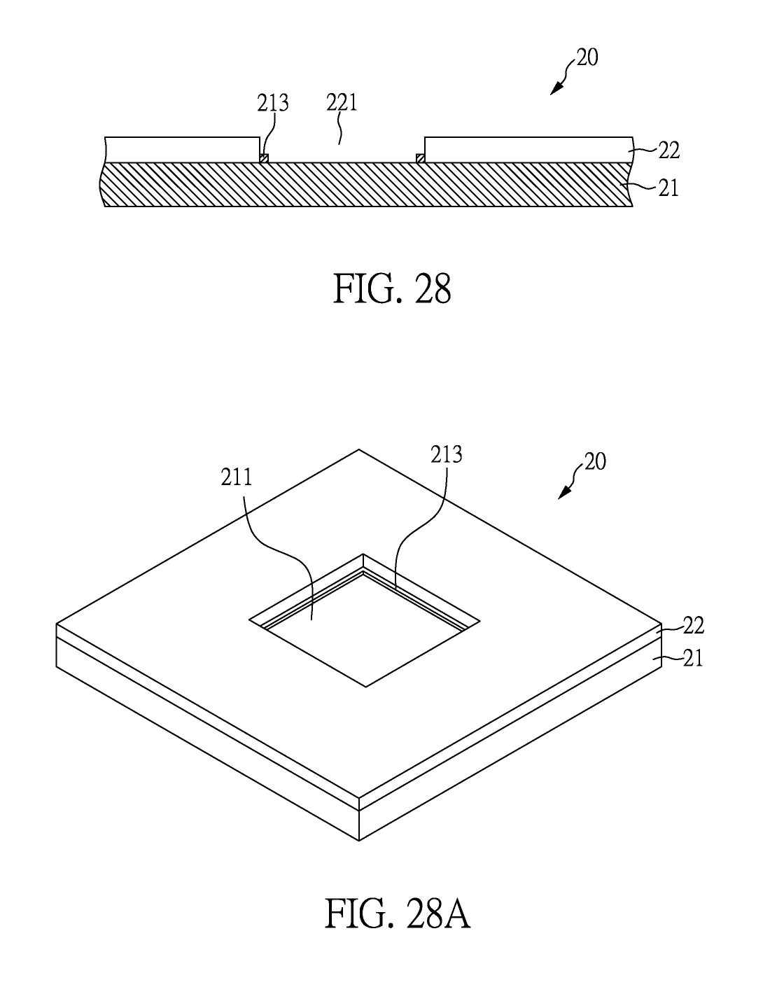

FIGS. 28 and 28A are cross-sectional and top perspective views, respectively, of heat sink 20 with alignment guide 213 inserted into aperture 221 of base layer 22. Base layer 22 is laminated onto metallic base sheet 21 with alignment guide 213 aligned with and inserted into aperture 221 of base layer 22. Base layer 22 can be epoxy, BT, polyimide and other kind of resin or resin/glass composite. In this illustration, base layer 22 has a thickness of 0.21 mm to match 0.15 mm chip and 0.05 mm conductive bump. As a result, cavity 211 can be defined by aperture 221 of base layer 22 on metallic base sheet 21.

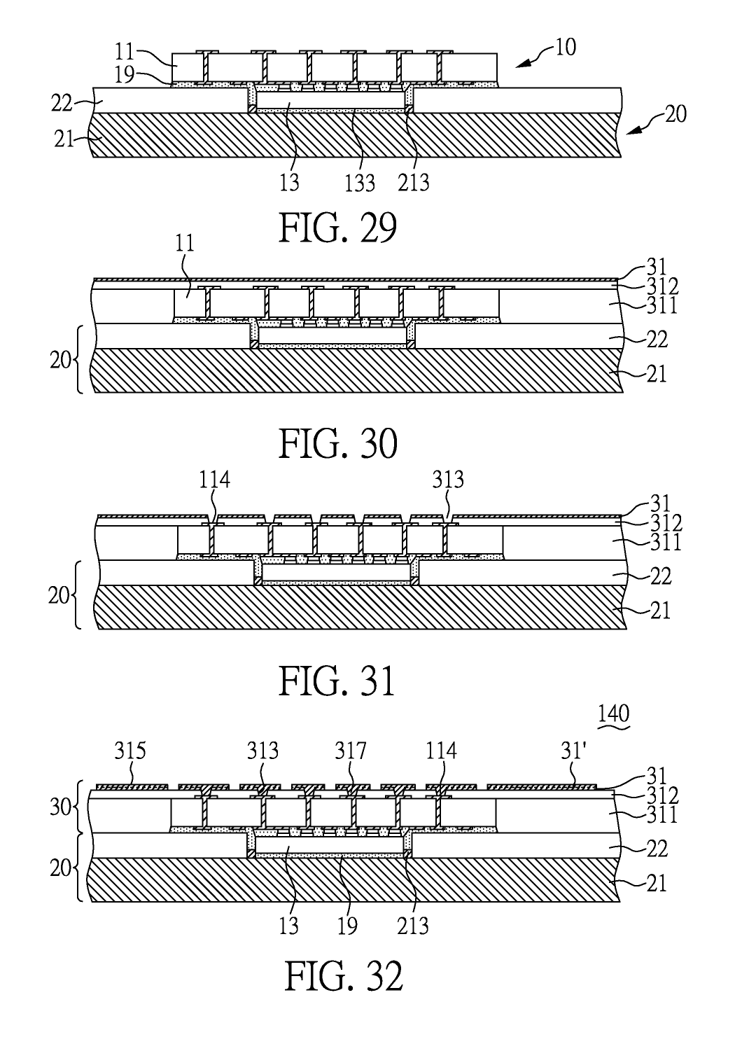

FIG. 29 is a cross-sectional view of the structure with chip-on-interposer package 10 attached on heat sink 20 using adhesive 19. Interposer 11 and chip 13 are attached on heat sink 20 with chip 13 inserted into cavity 211 and alignment guide 213 laterally aligned with peripheral edges of chip 13. Adhesive 19 surrounds the embedded chip 13, and the squeezed out portion contacts and is sandwiched between first surface 111 of interposer 11 and base layer 22. Alignment guide 213 extends from the cavity bottom and extends beyond inactive surface 133 of interposer 13 in the upward direction and is in close proximity to peripheral edges of chip 13 to provide critical placement accuracy for chip-on-interposer package 10.

FIG. 30 is a cross-sectional view of the structure with balancing layer 311, first insulating layer 312 and first metal sheet 31 laminated/coated on interposer 11 and heat sink 20. Balancing layer 311 contacts and covers base layer 22 of heat sink 20 and sidewalls of interposer 11. First insulating layer 312 contacts and provides robust mechanical bonds between first metal sheet 31 and interposer 11 and between first metal sheet 31 and balancing layer 311.

FIG. 31 is a cross-sectional view of the structure provided with first via openings 213. First via openings 213 extend through first metal sheet 31 and first insulating layer 312 and are aligned with second contact pads 114 of interposer 11.

Referring now to FIG. 32, first conductive traces 315 are formed on first insulating layer 312 by depositing first plated layer 31′ on first metal sheet 31 and into first via openings 313, and then patterning first metal sheet 31 as well as first plated layer 31′ thereon. First conductive traces 315 extend from first insulating layer 312 in the upward direction, extend laterally on first insulating layer 312 and extend into first via openings 313 in the downward direction to form first conductive vias 317 in direct contact with second contact pads 114 of interposer 11.

Accordingly, as shown in FIG. 32, semiconductor assembly 140 is accomplished and includes interposer 11, chip 13, heat sink 20 and build-up circuitry 30. Chip 13 is electrically coupled to the pre-fabricated interposer 11 by flip chip process to form chip-on-interposer package 10. Chip-on-interposer package 10 is attached on heat sink 20 using adhesive 19 with chip 13 positioned within cavity 211 and alignment guide 213 laterally aligned with and in close proximity to peripheral edges of chip 13. Adhesive 19 contacts and provides robust mechanical bonds between interposer 11 and heat sink and between chip 13 and heat sink 20. Build-up circuitry 30 is electrically coupled to interposer 11 through first conductive vias 317 and provides fan out routing/interconnection.

The assemblies described above are merely exemplary. Numerous other embodiments are contemplated. In addition, the embodiments described above can be mixed-and-matched with one another and with other embodiments depending on design and reliability considerations. The chip can share or not share the cavity with other chips. For instance, a cavity can accommodate a single chip, and the heat sink can include multiple cavities arranged in an array for multiple chips. Alternatively, numerous chips can be positioned within a single cavity. Likewise, a chip can share or not share the interposer with other chips. For instance, a single chip can be electrically connected to the interposer. Alternatively, numerous chips may be coupled to the interposer. For instance, four small chips in a 2×2 array can be coupled to the interposer and the interposer can include additional contact pads to receive and route additional chip pads. Also, the build-up circuitry can include additional conductive traces to accommodate additional contact pads of the interposer.

The chip can be a packaged or unpackaged chip. Furthermore, the chip can be a bare chip, or a wafer level packaged die, etc. The alignment guide can be customized for the interposer or the chip. For instance, the alignment guide can have a pattern that defines a square or rectangular area with the same or similar topography as the interposer or the chip.

The term “adjacent” refers to elements that are integral (single-piece) or in contact (not spaced or separated from) with one another. For instance, the build-up circuitry is adjacent to the interposer, but not adjacent to the chip.

The term “overlap” refers to above and extending within a periphery of an underlying element. Overlap includes extending inside and outside the periphery or residing within the periphery. For instance, in the cavity-down position, the heat sink overlaps the chip since an imaginary vertical line intersects the heat sink and the chip, regardless of whether another element such as the die attach is between the chip and the heat sink and is intersected by the line, and regardless of whether another imaginary vertical line intersects the heat sink but not the chip (outside the cavity). Moreover, overlap is synonymous with over and overlapped by is synonymous with under or beneath.

The term “contact” refers to direct contact. For instance, the first conductive vias contact the second contact pads of the interposer but do not contact the first contact pads of the interposer.

The term “cover” refers to incomplete and complete coverage in a vertical and/or lateral direction. For instance, in the cavity-up position, the metallic base sheet covers the chip in the downward direction regardless of whether another element such as the adhesive is between the metallic base sheet and the chip.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening” and “aperture” refer to a through-hole and are synonymous. For instance, in the cavity-up position, the alignment guide is exposed by the base layer in the upward direction when it is inserted into the aperture in the base layer.

The term “inserted” refers to relative motion between elements. For instance, the chip is inserted into the cavity of the heat sink regardless of whether the chip is stationary and the heat sink moves towards the chip, the heat sink is stationary and the chip moves towards the heat sink or the chip and the heat sink both approach the other.

The phrase “aligned with” refers to relative position between elements regardless of whether elements are spaced from or adjacent to one another or one element is inserted into and extends into the other element. For instance, the alignment guide is laterally aligned with the interposer since an imaginary horizontal line intersects the alignment guide and the interposer, regardless of whether another element is between the alignment guide and the interposer and is intersected by the line, and regardless of whether another imaginary horizontal line intersects the interposer but not the alignment guide or intersects the alignment guide but not the interposer. Likewise, the first via opening is aligned with the second contact pads of the interposer.

The phrase “in close proximity to” refers to a gap between elements not being wider than the maximum acceptable limit. As known in the art, when the gap between the alignment guide and the interposer is not narrow enough, the location error of the interposer due to the lateral displacement of the interposer within the gap may exceed the maximum acceptable error limit. In some cases, once the location error of the interposer goes beyond the maximum limit, it is impossible to align the predetermined portion of the interposer with a laser beam, resulting in the electrical connection failure between the interposer and the build-up circuitry. According to the pad size of the interposer, those skilled in the art can ascertain the maximum acceptable limit for a gap between the interposer and the alignment guide through trial and error to ensure the conductive vias being aligned with the contact pads of the interposer. Thereby, the descriptions “the alignment guide is in close proximity to the peripheral edges of the interposer” and “the alignment guide is in close proximity to the peripheral edges of the chip” mean that the gap between the alignment guide and the peripheral edges of the interposer or the chip is narrow enough to prevent the location error of the interposer from exceeding the maximum acceptable error limit.

The phrases “mounted on”, “attached on”, “attached onto”, “laminated on” and “laminated onto” include contact and non-contact with a single or multiple support element(s). For instance, the interposer can be attached on the heat sink regardless of whether it contacts the heat sink or is separated from the heat sink by an adhesive.

The phrases “electrical connection”, “electrically connected”, “electrically coupled” and “electrically couples” refer to direct and indirect electrical connection. For instance, the first conductive trace provides an electrical connection between the terminal pad and the second contact pad of interposer regardless of whether the first conductive trace is adjacent to the terminal pad or electrically connected to the terminal pad by the second conductive trace.

The term “above” refers to upward extension and includes adjacent and non-adjacent elements as well as overlapping and non-overlapping elements. For instance, in the cavity-up position, the alignment guide extends above, is adjacent to and protrudes from the flat surface of the heat sink in the upward direction.

The term “below” refers to downward extension and includes adjacent and non-adjacent elements as well as overlapping and non-overlapping elements. For instance, in the cavity-down position, the interposer extends below the cavity in the downward direction, and the alignment guide also extends below the cavity even though it is not adjacent to or overlapped by the cavity.

The “first vertical direction” and “second vertical direction” do not depend on the orientation of the assembly, as will be readily apparent to those skilled in the art. For instance, the first surface of the interposer faces the first vertical direction and the second surface of the interposer faces the second vertical direction regardless of whether the assembly is inverted. Likewise, the alignment guide is “laterally” aligned with the interposer or the chip in a lateral plane regardless of whether the assembly is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the cavity-up position, and the first vertical direction is the upward direction and the second vertical direction is the downward direction in the cavity-down position.

The thermally enhanced semiconductor assembly according to the present invention has numerous advantages. For instance, the chip is coupled to the interposer before built-in process, and therefore can avoid warping problem caused by substrate fabrication. The interposer provides first level fan-out routing/interconnection for the embedded chip/chips, whereas the build-up circuitry provides second level fan-out routing/interconnection. As the build-up circuitry is formed on the interposer, the manufacturing yield is greatly improved compared to the types where build-up circuitry is directly formed on the embedded chip. The alignment guide can provide critical placement accuracy for the interposer. As such, the shape or depth of the cavity that houses the embedded chip is not a critical parameter that needs tightly controlled. The heat sink can provide essential thermal dissipation, electromagnetic shielding and moisture barrier for the embedded chip, and also provides mechanical support for the chip, the interposer and the build-up circuitry. The direct electrical connection without solder between the interposer and the build-up circuitry is advantageous to high I/O and high performance. The assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a thermally enhanced semiconductor assembly with embedded chip and interposer, comprising:
providing a chip;
providing an interposer that includes a through via, a first contact pad on a first surface and a second contact pad on an opposite second surface, wherein the through via electrically couples the first contact pad and the second contact pad;
electrically coupling the chip to the first contact pad of the interposer by a conductive bump or a wire;
providing a heat sink with a cavity;
attaching the chip and the interposer on the heat sink using an adhesive with the chip inserted into the cavity and the interposer laterally extending beyond the cavity; and
forming a build-up circuitry on the second surface of the interposer, including electrically coupling the second contact pad of the interposer through a first conductive via of the build-up circuitry.

2. The method of claim 1, wherein the step of electrically coupling the chip to the interposer is performed on panel scale, and a singulation step is executed to separate individual interposer pieces each with the chip electrically coupled thereon before the step of attaching the chip and the interposer on the heat sink.

3. The method of claim 1, wherein the heat sink further includes an alignment guide beyond the cavity, and the interposer is attached to the heat sink with the alignment guide laterally aligned with and in close proximity to peripheral edges of the interposer.

4. The method of claim 3, wherein providing the heat sink includes:
providing a metallic base sheet;
forming the cavity in the metallic base sheet; and
forming the alignment guide around an entrance of the cavity by removing a selected portion of the metallic base sheet or by pattern deposition of a metal or a plastic material on the metallic base sheet.

5. The method of claim 3, wherein providing the heat sink includes:
providing a laminated substrate that includes a dielectric layer and a metallic base sheet;
forming the alignment guide on the dielectric layer by removing a selected portion of a metal layer on the dielectric layer or by pattern deposition of a metal or a plastic material on the dielectric layer; and
forming the cavity that extends through the dielectric layer and optionally extends into the metallic base sheet.

6. The method of claim 3, wherein a gap in between the interposer and the alignment guide is in a range of 5 to 50 microns.

7. The method of claim 3, wherein the alignment guide has a height in a range of 5 to 200 microns.

8. The method of claim 1, wherein the heat sink further includes an alignment guide within the cavity, and the chip is attached to the heat sink with the alignment guide laterally aligned with and in close proximity to peripheral edges of the chip.

9. The method of claim 8, wherein providing the heat sink includes:
providing a metallic base sheet;
forming the alignment guide at a surface of the metallic base sheet by removing a selected portion of the metallic base sheet or by pattern deposition of a metal or a plastic material on the metallic base sheet; and
providing a base layer on the metallic base sheet with the alignment guide located within an aperture of the base layer.

10. The method of claim 8, wherein a gap in between the chip and the alignment guide is in a range of 5 to 50 microns.

11. The method of claim 8, wherein the alignment guide has a height in a range of 5 to 200 microns.

12. The method of claim 1, wherein forming the build-up circuitry includes:
providing a balancing layer that laterally covers sidewalls of the interposer;
providing a first insulating layer on the second surface of the interposer and the balancing layer;
forming a first via opening that extends through the first insulating layer and is aligned with the second contact pad of the interposer; and
forming a first conductive trace that extends laterally on the first insulating layer and extends through the first via opening to form the first conductive via in direct contact with the second contact pad of the interposer.

13. The method of claim 12, wherein forming the build-up circuitry includes:
forming an additional first via opening that extends through the first insulating layer and the balancing layer and is aligned with a selected portion of the heat sink; and
forming the first conductive trace that extends through the additional first via opening to form an additional first conductive via in direct contact with the selected portion of the heat sink.

14. A thermally enhanced semiconductor assembly with embedded chip and interposer prepared by a method that comprises steps of:
providing a chip;
providing an interposer that includes a through via, a first contact pad on a first surface and a second contact pad on an opposite second surface, wherein the through via electrically couples the first contact pad and the second contact pad;
electrically coupling the chip to the first contact pad of the interposer by a conductive bump or a wire;
providing a heat sink with a cavity;
attaching the chip and the interposer on the heat sink using an adhesive with the chip inserted into the cavity and the interposer laterally extending beyond the cavity; and
forming a build-up circuitry on the second surface of the interposer, including electrically coupling the second contact pad of the interposer through a first conductive via of the build-up circuitry.
